(19) United States
(12) Patent Application Publication
(10) Pub. No.: US 2018/0241000 A1
(43) Pub. Date: Aug. 23, 2018

(54) ORGANIC EL DISPLAY DEVICE

(71) Applicant: Sharp Kabushiki Kaisha, Sakai City, Osaka (JP)

(72) Inventors: Tetsuya OKAMOTO, Sakai City (JP); Takeshi HIRASE, Sakai City (JP); Takashi OCHI, Sakai City (JP); Tohru SENOO, Sakai City (JP); Tohru SONODA, Sakai City (JP); Mamoru ISHIDA, Sakai City (JP)

(21) Appl. No.: 15/757,989

(22) PCT Filed: Sep. 1, 2016
(86) PCT No.: PCT/JP2016/004002

§ 371 Date: Mar. 7, 2018

(30) Foreign Application Priority Data
Sep. 8, 2015 (JP) 2015-176586

(51) Int. Cl. H01L 51/52; H01L 51/00; H01L 51/56

(52) U.S. Cl. CPC H01L 51/5253; H01L 51/524; H01L 51/56; H01L 51/0097

(57) ABSTRACT

An organic EL display device 1 includes: a flexible plastic substrate 10; a first sealing film 3 on the plastic substrate 10; an organic EL element layer 5 above the first sealing film 3; and a second sealing film 6 provided on the organic EL element layer 5, being in contact with the first sealing film 3, and covering, together with the first sealing film 3, the organic EL element layer 5. A sealer 2 is provided to cover an interface 25 between the first and second sealing films 3 and 6.

### TECHNICAL FIELD

The present invention relates to an organic EL display device including an organic electroluminescence element (hereinafter referred to as the “organic EL element”).

### BACKGROUND ART

In recent years, liquid crystal display devices are often used as flat panel displays in various fields. However, contrast and shade greatly vary depending on viewing angles. A need for a light source such as a backlight hinders lower power consumption. Reduction in the thickness and weight of a liquid crystal display device is limited. These serious problems still remain. Liquid crystal display devices have serious problems also in flexibility.

To address the problems, self-luminous organic EL display devices including organic EL elements are expected in place of liquid crystal display devices. In an organic EL element, a current flows through organic EL layers sandwiched between an anode and a cathode so that organic molecules forming the organic EL layers emit light. Organic EL display devices including such an organic EL element, which are self-luminous, have their thickness and weight easily reduced, and consume less power. The organic EL display devices, which have a wide viewing angle, receive great attention as flat panels that have an advantage over liquid crystal panels.

Organic EL display devices including a plastic substrate draw special attention. The plastic substrate has higher flexibility, higher shock resistance, and lower weight than a glass substrate. Such a plastic substrate would provide new organic EL display devices beyond typical displays including a glass substrate.

However, in general, after a certain period of drive, light-emitting characteristics, such as brightness and uniformity in light emission, of an organic EL element deteriorate significantly from the initial state. The deterioration in the light-emitting characteristics attributes to deterioration of an organic layer due to moisture of outside air, which has entered the organic EL element, or separation of the organic layer from an electrode.

To address the problems, a technique of providing a sealing film to reduce entry of gas such as moisture is disclosed. More specifically, an organic EL display device is disclosed which includes, for example, a flexible plastic substrate (film substrate), a barrier film (first sealing film) provided on the plastic substrate, organic EL elements formed on the barrier film, and a sealing film (second sealing film) provided on the barrier film to cover the organic EL elements. Such a configuration may reduce the deterioration of the organic EL elements due to moisture (see, for example, Patent Document 1).

### CITATION LIST

### Patent Document

Patent Document 1: Japanese Unexamined Patent Publication No. 2013-254747

### SUMMARY OF THE INVENTION

### Technical Problem

However, in the configuration of Patent Document 1, the boundary (interface) between the barrier film and the sealing film is exposed, and moisture can enter through this boundary. It is therefore difficult to block the entry of moisture with the configuration of Patent Document 1.

As can be seen, organic EL display devices have a problem: the barrier performance against moisture can be deteriorated due to not only exposure of the interface between a barrier film and a sealing film, but also exposure of the interface between a substrate and an organic EL element layer, and the interface between the substrate and a sealing film.

In view of the foregoing problem, it is therefore an object of the present invention to provide an organic EL display device which is capable of reducing deterioration of an organic EL element by preventing or reducing entry of moisture through, for example, the boundary between a barrier film and a sealing film.

### Solution to the Problem

To achieve the above object, an organic EL display device according to a first aspect of the present invention includes: a substrate, a first sealing film on the substrate; an organic EL element layer above the first sealing film; and a second sealing film provided on the organic EL element layer, being in contact with the first sealing film, and covering, together with the first sealing film, the organic EL element layer, wherein a sealer is provided to cover an interface between the first and second sealing films.

An organic EL display device according to a second aspect of the present invention includes: a substrate; a first sealing film on the substrate; an organic EL element layer above the first sealing film; and a second sealing film provided on the organic EL element layer, being in contact with the first sealing film, and covering, together with the first sealing film, the organic EL element layer, wherein the second sealing film includes a plurality of barrier layers and a plurality of stress relief layers stacked alternately, an outermost barrier layer of the plurality of barrier layers located opposite to the organic EL element layer covers an interface between the first and second sealing films.

An organic EL display device according to a third aspect of the present invention includes: a substrate; a first sealing film on the substrate; an organic EL element layer above the first sealing film; and a second sealing film provided on the organic EL element layer, being in contact with an upper surface of an end portion of the substrate, and covering an interface between the substrate and the organic EL element layer.

### Advantages of the Invention

The present invention can ensure barrier performance against moisture, and contributes to prevention of deterioration of an organic EL element.

### BRIEF DESCRIPTION OF THE DRAWINGS

FIG. 1 is a cross-sectional view of an organic EL display device according to a first embodiment of the present invention.

FIG. 2 is a cross-sectional view illustrating an organic EL element layer and a thin-film transistor layer which are included in the organic EL display device according to the first embodiment of the present invention.

FIG. 3 is a cross-sectional view illustrating an organic EL layer forming part of an organic EL element included in the organic EL display device according to the first embodiment of the present invention.

FIG. 4 is a cross-sectional view illustrating a first sealing film included in the organic EL display device according to the first embodiment of the present invention.

FIG. 5 is a cross-sectional view illustrating a second sealing film included in the organic EL display device according to the first embodiment of the present invention.

FIG. 6 is a cross-sectional view illustrating a method for manufacturing the organic EL display device according to the first embodiment of the present invention.

FIG. 7 is a cross-sectional view illustrating the method for manufacturing the organic EL display device according to the first embodiment of the present invention.

FIG. 8 is a cross-sectional view illustrating the method for manufacturing the organic EL display device according to the first embodiment of the present invention.

FIG. 9 is a cross-sectional view illustrating the method for manufacturing the organic EL display device according to the first embodiment of the present invention.

FIG. 10 is a cross-sectional view of an organic EL display device according to a second embodiment of the present invention.

FIG. 11 is a cross-sectional view illustrating a method for manufacturing the organic EL display device according to the second embodiment of the present invention.

FIG. 12 is a cross-sectional view of an organic EL display device according to a variation of the present invention.

FIG. 13 is a cross-sectional view of an organic EL display device according to a variation of the present invention.

### DESCRIPTION OF EMBODIMENTS

Embodiments of the present invention will now be described in detail with reference to the drawings. The present invention is not limited to the following embodiments.

### First Embodiment

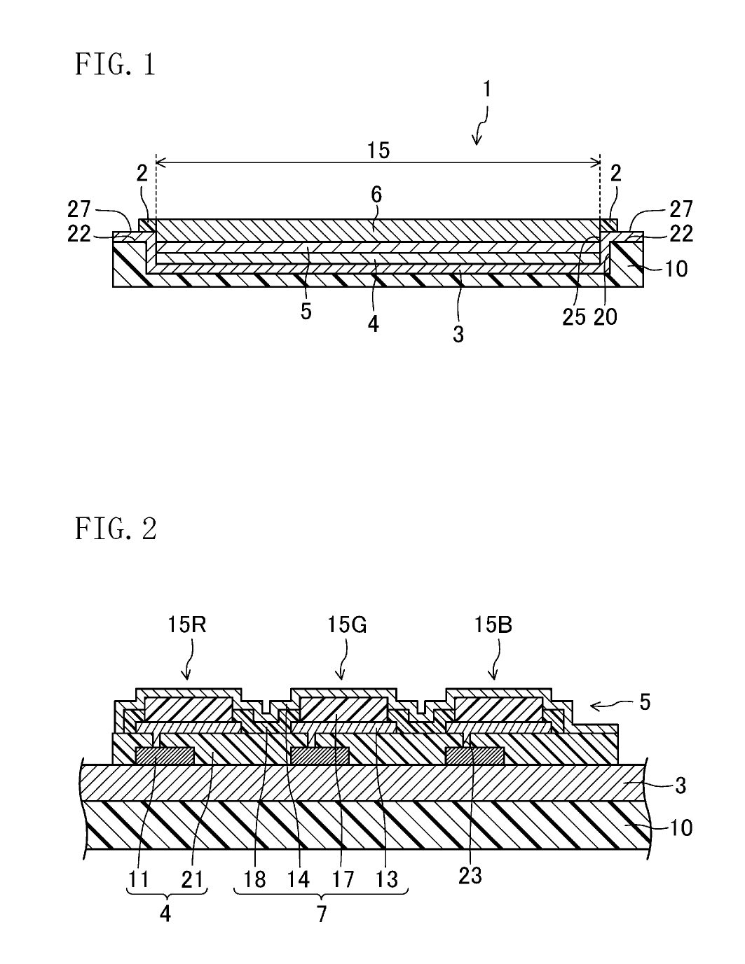

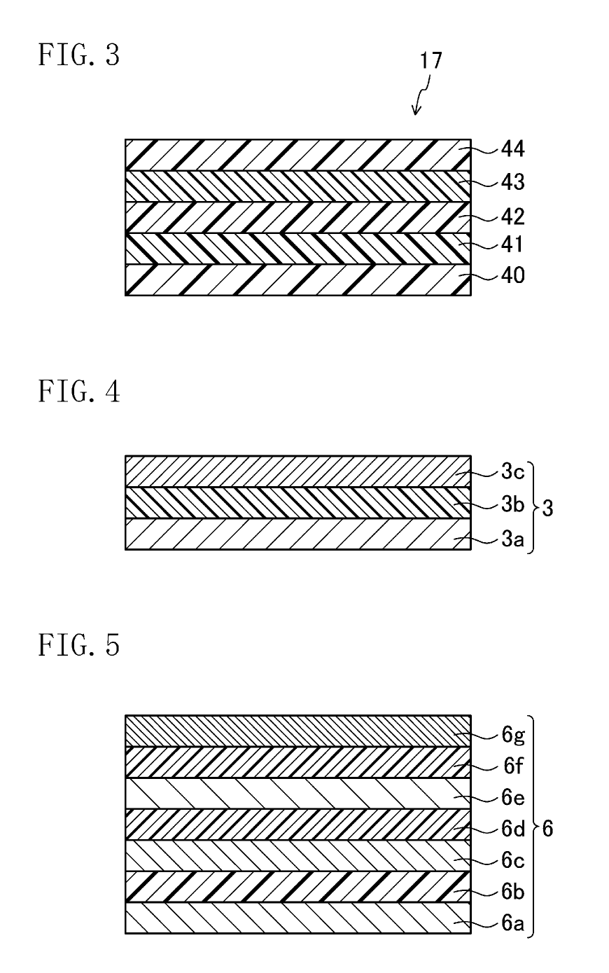

FIG. 1 is a cross-sectional view of an organic EL display device according to a first embodiment of the present invention. FIG. 2 is a cross-sectional view illustrating an organic EL element layer and a thin-film transistor layer which are included in the organic EL display device according to the first embodiment of the present invention. FIG. 3 is a cross-sectional view illustrating an organic EL layer forming part of an organic EL element included in the organic EL display device according to the first embodiment of the present invention.

As illustrated in FIG. 1, the organic EL display device 1 includes: a plastic substrate 10 as an element substrate; a first sealing film 3 on the plastic substrate 10; a thin-film transistor layer 4 on the first sealing film 3; and an organic EL element layer 5 on the thin-film transistor layer 4. The organic EL display device 1 also includes a second sealing film 6 which is provided on the organic EL element layer 5 and is in contact with the first sealing film 3. Thus, the second sealing film 6 and the first sealing film 3 together cover the organic EL element layer 5.

The plastic substrate 10 is a flexible film-like substrate made of an insulating resin material. Examples of the resin material for the plastic substrate 10 include organic materials such as polyimide resin and acrylic resin.

As illustrated in FIG. 1, the plastic substrate 10 has a recess 20 which receives therein the thin-film transistor layer 4 and the organic EL element layer 5. Specifically, the first sealing film 3 is formed on a surface of the recess 20, and the thin-film transistor layer 4 and the organic EL element layer 5 are received in the recess 20.

As illustrated in FIG. 1, the organic EL display device 1 includes a display region 15 in which organic EL elements 7 forming the organic EL element layer 5 are arranged. Specifically, in the display region 15, the organic EL elements 7 are arranged in a matrix above the plastic substrate 10. As illustrated in FIG. 2, the display region 15 is formed by arranging pixel regions 15R emitting red light, pixel regions 15G emitting green light, and pixel regions 15B emitting blue light in a predetermined pattern.

As illustrated in FIG. 2, each organic EL element 7 includes, above the barrier film 3, a predetermined array (e.g., a matrix) of multiple first electrodes (anodes) 13, organic EL layers 17 on the respective first electrodes 13, and a second electrode 14 on the organic EL layers 17.

Each organic EL element 7 also includes an edge cover 18 to cover the peripheral edge of the associated first electrode 13 and regions without the first electrode 13. Each edge cover 18 is interposed between the pixel regions 15R, 15G, and 15B, and functions as a partition segmenting the pixel regions 15R, 15G, and 15B.

Moreover, as illustrated in FIG. 2, the thin-film transistor layer 4 includes thin-film transistors (TFTs) 11 and an interlayer insulating film 21. Each of the TFTs 11 is formed on the barrier film 3 and electrically connected to an associated one of the first electrodes 13 arranged in the predetermined array. The interlayer insulating film 21 is formed on the barrier film 3 to cover the TFTs 11.

The first electrodes 13 function to inject holes (positive holes) into organic EL layers 17. The first electrodes 13 preferably contain a material with a high work function. This is because a material with a high work function allows the first electrodes 13 to inject positive holes into the organic EL layers 17 with higher efficiency. Furthermore, as illustrated in FIG. 1, the first electrodes 13 are formed on the interlayer insulating film 21.

Examples of the material for the first electrodes 13 include metal materials such as silver (Ag), aluminum (Al), vanadium (V), cobalt (Co), nickel (Ni), tungsten (W), gold (Au), calcium (Ca), titanium (Ti), yttrium (Y), sodium (Na), ruthenium (Ru), manganese (Mn), indium (In), magnesium (Mg), lithium (Li), ytterbium (Yb), and lithium fluoride (LiF). The first electrodes 13 may also be an alloy of, for example, magnesium (Mg)/copper (Cu), magnesium (Mg)/silver (Ag), sodium (Na)/potassium (K), astatine (At)/astatine dioxide (AtO₂), lithium (Li)/aluminum (Al), lithium (Li)/calcium (Ca)/aluminum (Al), or lithium fluoride (LiF)/calcium (Ca)/aluminum (Al). The first electrodes 13 may also be a conductive oxide such as tin oxide (SnO), zinc oxide (ZnO), indium tin oxide (ITO), and indium zinc oxide (IZO).

Moreover, the first electrodes 13 may be multilayers containing the above materials. Examples of materials with a high work function include indium tin oxide (ITO) and indium zinc oxide (IZO).

The interlayer insulating film 21 is formed on the barrier film 3, and functions to planarize the surface of the film on which the TFTs 11 are provided. Due to the interlayer insulating film 21, the first electrodes 13 and the organic EL layers 17 are formed flat on or above the interlayer insulating film 21. That is, the planarization using the interlayer insulating film 21 reduces the risk that steps, protrusions, and recesses of the underlayers in the organic EL display device 1 influence the shape of the surface of the first electrodes 13, causing light emission by the organic EL layers 17 to be non-uniform. The interlayer insulating film 21 contains a highly transparent, low-cost organic resin material such as acrylic resin.

As illustrated in FIG. 2, the first electrodes 13 are electrically connected to the TFTs 11 via contact holes 23 formed in the interlayer insulating film 21.

Each organic EL layer 17 is formed on a surface of an associated one of the first electrodes 13 arranged in a matrix. As illustrated in FIG. 3, each organic EL layer 17 includes a positive hole injection layer 40, a positive hole injection layer 41, a light-emitting layer 42, an electron transport layer 43, and an electron injection layer 44. The positive hole transport layer 41 is formed on a surface of the positive hole injection layer 40. The light-emitting layer 42 is formed on a surface of the positive hole transport layer 41, and emits either red, green, or blue light. The electron transport layer 43 is formed on a surface of the light-emitting layer 42. The electron injection layer 44 is formed on a surface of the electron transport layer 43. Each organic EL layer 17 is formed by sequentially stacking the positive hole injection layer 40, the positive hole transport layer 41, the light-emitting layer 42, the electron transport layer 43, and the electron injection layer 44. The organic EL layer 17 may be smaller in area than the underlying first electrodes 13. Alternatively, the organic EL layer 17 may be larger in area than the underlying first electrodes 13 to cover the first electrodes 13.

The positive hole injection layer 40 is also called an anode buffer layer, and used to bring the energy levels of the first electrodes 13 and the organic EL layers 17 close to each other and increase efficiency in injection of positive holes from the first electrodes 13 into the organic EL layers 17.

Examples of the material for the positive hole injection layer 40 include triazole derivatives, oxadiazole derivatives, imidazole derivatives, polyarylalkane derivatives, pyrazoline derivatives, phenylenediamine derivatives, oxazole derivatives, styrylanthracene derivatives, fluorenone derivatives, hydrazone derivatives, and stilbene derivatives.

The positive hole transport layer 41 increases the efficiency in transporting positive holes from the first electrodes 13 to the organic EL layers 17. Examples of the material for the positive hole transport layer 41 include porphyrin derivatives, aromatic tertiary amine compounds, styrylamine derivatives, polyvinylcarbazole, poly-p-phenylene vinylene, polysilane, triazole derivatives, oxadiazole derivatives, imidazole derivatives, polyarylalkane derivatives, pyrazoline derivatives, pyrazolone derivatives, phenylenediamine derivatives, arylamine derivatives, amine-substituted chalcone derivatives, oxazole derivatives, styrylanthracene derivatives, fluorenone derivatives, hydrazone derivatives, stilbene derivatives, hydrogenated amorphous silicon, hydrogenated amorphous silicon carbide, zinc sulfide, and zinc selenide.

The light-emitting layer 42 is a region in which the positive holes and the electrons are injected thereinto from the first electrodes 13 and the second electrode 14 and recombine with each other when a voltage is applied from the first electrodes 13 and the second electrode 14. This light-emitting layer 42 is made of a material with high luminous efficiency. Examples of the material include metal oxinoid compounds [8-hydroxyquinoline metal complexes], naphthalene derivatives, anthracene derivatives, diphenylethylene derivatives, vinylacetone derivatives, triphenylamine derivatives, butadiene derivatives, coumarin derivatives, benzoxazole derivatives, oxadiazole derivatives, oxazole derivatives, benzimidazole derivatives, thiadiazole derivatives, benzothiazole derivatives, styryl derivatives, styrylamine derivatives, bisstyrylbenzene derivatives, trisstyrylbenzene derivatives, perylene derivatives, perinone derivatives, aminopyrene derivatives, pyridine derivatives, rodamine derivatives, acridine derivatives, phenoxazone, quinacridone derivatives, rubrene, poly-p-phenylene vinylene, and polysilane.

The electron transport layer 43 functions to efficiently move electrons to the light-emitting layer. Examples of the material for the electron transport layer 43 include, as organic compounds, oxadiazole derivatives, triazole derivatives, benzoquinone derivatives, naphthoquinone derivatives, anthraquinone derivatives, tetracyanoanthraquinodimethane derivatives, diphenoquinone derivatives, fluorenone derivatives, silole derivatives, and metal oxinoid compounds.

The electron injection layer 44 brings the energy levels of the second electrode 14 and the organic EL layers 17 close to each other to increase the efficiency in injecting electrons from the second electrode 14 into the organic EL layers 17, thereby reducing the drive voltage of the organic EL element 7. The electron injection layer 44 may also be called a cathode buffer layer. Examples of the material for the electron injection layer 44 include: inorganic alkaline compounds such as lithium fluoride (LiF), magnesium fluoride (MgF₂), calcium fluoride (CaF₂), strontium fluoride (SrF₂), barium fluoride (BaF₂); Al₂O₃; and SrO.

The second electrode 14 functions to inject electrons into the organic EL layers 17. It is more preferable that the second electrode 14 contain a material with a low work function. This is because a material with a low work function allows the second electrode 14 to inject electrons into the organic EL layers 17 with higher efficiency. As illustrated in FIG. 2, the second electrode 14 is formed on the organic EL layers 17.

Examples of materials for the second electrode 14 include silver (Ag), aluminum (Al), vanadium (V), cobalt (Co), nickel (Ni), tungsten (W), gold (Au), calcium (Ca), titanium (Ti), yttrium (Y), sodium (Na), ruthenium (Ru), manganese (Mn), indium (In), magnesium (Mg), lithium (Li), ytterbium (Yb), and lithium fluoride (LiF). The second electrode 14 may also be an alloy of, e.g., magnesium (Mg)/copper (Cu), magnesium (Mg)/silver (Ag), sodium (Na)/potassium (K), astatine (At)/astatine dioxide (AtO₂), lithium (Li)/aluminum (Al), lithium (Li)/calcium (Ca)/aluminum (Al), and lithium fluoride (LiF)/calcium (Ca)/aluminum (Al). The second electrode 14 may also contain a conductive oxide such as tin oxide (SnO), zinc oxide (ZnO), indium tin oxide (ITO), or indium zinc oxide (IZO). The second electrode 14 may be a multilayer containing the above materials.

A material with a low work function may be, for example, magnesium (Mg), lithium (Li), lithium fluoride (LiF), magnesium (Mg)/copper (Cu), magnesium (Mg)/silver (Ag), sodium (Na)/potassium (K), lithium (Li)/aluminum (Al), lithium (Li)/calcium (Ca)/aluminum (Al), or lithium fluoride (LiF)/calcium (Ca)/aluminum (Al).

The edge covers 18 function to reduce short-circuit between the first electrodes 13 and the second electrode 14. Thus, the edge covers 18 preferably cover entire peripheral edges of the first electrodes 13.

Examples of the material for the edge covers 18 include silicon dioxide (SiO₂), silicon nitride (SiNₓ, where x is a positive number) such as Si₃N₄, and silicon oxynitride (SiNO).

As illustrated in FIG. 4, the first sealing film 3, which is provided on the surface of the plastic substrate 10, is a multilayer including a barrier layer 3a in contact with the plastic substrate 10, a stress relief layer 3b on a surface of the barrier layer 3a, and a barrier layer 3c on a surface of the stress relief layer 3b.

To ensure sufficient barrier performance against moisture and sufficient stress relief performance, the first sealing film 3 preferably has a thickness ranging from 1.5 μm to 2.5 μm.

As illustrated in FIG. 5, the second sealing film 6 is a multilayer including barrier layers 6a, 6c, 6e, and 6g and stress relief layers 6b, 6d, and 6f stacked in an alternating manner.

To prevent the entry of foreign substances and to ensure sufficient barrier performance against moisture and sufficient stress relief performance, the second sealing film 6 preferably has a thickness ranging from 2.5 μm to 3.5 μm.

The material for each of the barrier layers 3a, 3c, 6a, 6c, 6e, and 6g is not limited to any particular material, as long as the material has high barrier performance against moisture. Examples of the material include inorganic materials such as silicon nitride (SiNₓ, where x is a positive number; e.g., Si₃N₄), silicon dioxide (SiO₂), and aluminum oxide (Al₂O₃).

The material for each of the stress relief layers 3b, 6b, 6d, and 6f is not limited to any particular material, as long as the material has high stress relief performance Examples of the material include organic materials such as silicon carbonitride (SiCN), polysiloxane, silicon oxycarbide (SiOC), acrylate, polyurea, parylene, polyimide, and polyamide.

As illustrated in FIG. 1, this embodiment has a feature in which a sealer 2 is provided to cover an interface 25 between the first and second sealing films 3 and 6 (i.e., a contact portion between the first and second sealing films 3 and 6).

This configuration can prevent the interface 25 between the first and second sealing films 3 and 6 from being exposed, enabling prevention of entry of moisture through the boundary between the first and second sealing films 3 and 6. This makes it possible to prevent deterioration of the organic EL elements 7 which may be caused by moisture.

Examples of the material for the sealer 2 include epoxy resin, ultraviolet (UV) curable resin such as acrylic resin, and thermosetting resin.

An exemplary method for manufacturing the organic EL display device according to this embodiment will now be described. FIGS. 6 to 9 are cross-sectional views illustrating the exemplary method for manufacturing the organic EL display device according to the first embodiment of the present invention.

First, as illustrated in FIG. 6, a plastic substrate 10 having, for example, a size of 320 mm×400 mm and a thickness of 0.7 mm, and including a recess 20 (having, for example, a thickness of 7 μm) is provided.

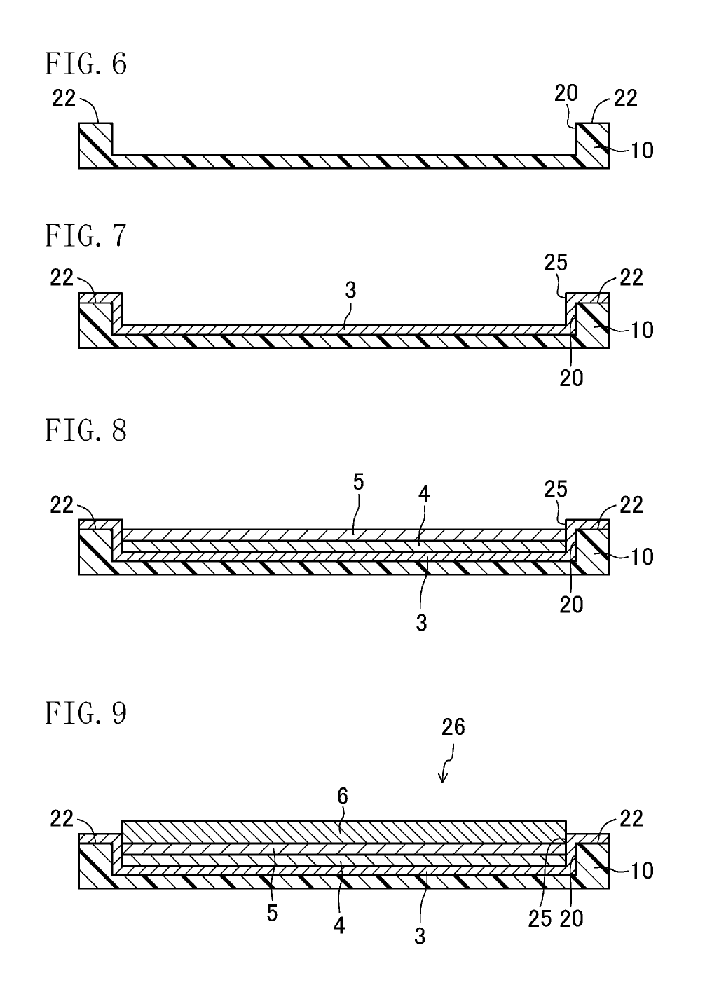

Next, as illustrated in FIG. 7, a first sealing film 3 is formed on a surface of the recess 20 formed in the plastic substrate 10.

More specifically, silicon nitride (SiNₓ, where x is a positive number) such as Si₃N₄ is deposited by plasma CVD, vacuum vapor deposition, sputtering, atomic layer deposition (ALD) or other methods, thereby forming a barrier layer 3a (having a thickness of, e.g., 500 nm thick) on the surface of the recess 20 of the plastic substrate 10.

Next, for example, silicon carbonitride (SiCN) is deposited by plasma CVD, vacuum vapor deposition, sputtering, atomic layer deposition (ALD) or other methods, thereby forming a stress relief layer 3b (having a thickness of, e.g., 500 nm thick) on a surface of the barrier layer 3a.

Next, like the barrier layer 3a described above, silicon nitride (SiNₓ, where x is a positive number) such as Si₃N₄ is deposited by plasma CVD, vacuum vapor deposition, sputtering, atomic layer deposition (ALD) or other methods, thereby forming a barrier layer 3c (having a thickness of, e.g., 500 nm thick) on a surface of the stress relief layer 3b. In this manner, the first sealing film 3 is formed on the surface of the recess 20 of the plastic substrate 10.

At this time, as illustrated in FIG. 7, the first sealing film 3 is formed also on upper surfaces 22 of end portions of the plastic substrate 10.

Next, as illustrated in FIG. 8, a thin-film transistor layer 4 including TFTs 11 and an interlayer insulating film 21 is formed on the first sealing film 3.

More specifically, as illustrated in FIG. 2, the TFTs 11 for driving organic EL elements 7 are formed at predetermined intervals on the first sealing film 3.

Next, a photosensitive acrylic resin is applied onto the first sealing film 3 having the TFTs 11 formed thereon by spin coating, and is exposed to a predetermined amount (e.g., 150 mJ/cm²) of light through an exposure mask with a predetermined exposure pattern. Then, development is performed using an alkaline developer. In this manner, the interlayer insulating film 21 with a thickness of, for example, 2 μm is formed. After the development, the interlayer insulating film 21 is baked in post-baking under a predetermined condition (e.g., at a temperature of 220° C. for 60 minutes).

At this time, as illustrated in FIG. 2, contact holes 23 (having a diameter of, for example, 5 μm) for electrically connecting first electrodes 13 to the TFTs 11 are formed in the interlayer insulating film 21.

Next, as illustrated in FIG. 8, an organic EL element layer 5 which includes the first electrodes 13, a second electrode 14, organic EL layers 17, and edge covers 18 is formed on the first thin-film transistor layer 4.

More specifically, as illustrated in FIG. 2, an indium tin oxide (ITO) film is formed by sputtering, exposed to light by photolithography and developed, and patterned by etching to form the first electrodes 13 on the interlayer insulating film 21. At this time, the first electrodes 13 are formed to have a thickness of approximately 100 nm, for example. After the development, the first electrodes 13 are baked in post-baking under a predetermined condition (e.g., at a temperature of 220° C. for 120 minutes). The first electrodes 13 are electrically connected to the TFTs 11 via the contact holes 23 formed in the interlayer insulating film 21.

Subsequently, a silicon dioxide film is formed at the peripheral edges of the first electrodes 13 by sputtering, exposed to light by photolithography and developed, and patterned by etching to form the edge covers 18 to cover the entire peripheral edges of the first electrodes 13. At this time, the edge covers 18 are formed to have a thickness of approximately 150 nm, for example.

Then, the organic EL layers 17 including a light-emitting layer 42 are formed on the first electrodes 13, and thereafter, the second electrode 14 is formed on the organic EL layers 17. The organic EL layers 17 and the second electrode 14 are formed by vapor deposition using a metal mask.

More specifically, first, the plastic substrate 10 including the first electrodes 13 is placed in a chamber of a vapor deposition system. The inside of the chamber of the vapor deposition system is kept at a vacuum degree from 1×10⁻⁵ pa to 1×10⁻⁴ Pa by a vacuum pump. The plastic substrate 10 including the first electrodes 13 is placed with two sides fixed to a pair of substrate receivers attached to the inside of the chamber.

From a deposition source, deposit materials for the positive hole injection layer 40, the positive hole transport layer 41, the light-emitting layer 42, the electron transport layer 43, and the electron injection layer 44 are sequentially evaporated to be deposited. In this manner, these layers are stacked to form the organic EL layers 17 in pixel regions as illustrated in FIG. 2.

Next, as illustrated in FIG. 2, the second electrode 14 is formed on the organic EL layers 17. As a result, the organic EL elements 7 including the first electrodes 13, the organic EL layers 17, the second electrode 14, and the edge covers 18 are formed above the plastic substrate 10.

Note that a crucible containing the deposit materials may be used as the deposition source, for example. The crucible is placed at a lower position inside the chamber, and provided with a heater, which heats the crucible.

The heat of the heater allows the temperature inside the crucible to reach the evaporation temperatures of the deposit material so that the deposit materials inside the crucible turn into vapor, and the vapor jumps out upward inside the chamber.

A specific exemplary method of forming the organic EL layers 17 and the second electrode 14 is as follows. First, on the first electrodes 13, which are patterned on the plastic substrate 10, the positive hole injection layer 40 made of m-MTDATA(4,4,4-tris(3-methylphenylphenylamino)triphenylamine) is formed to have a thickness of, for example, 25 nm in common among all of RGB pixels, via a mask.

Then, on the positive hole injection layer 40, the positive hole transport layer 41 made of α-NPD(4,4-bis(N-1-naphthyl-N-phenylamino)biphenyl) is formed, via a mask, to have a thickness of, for example, 30 nm in common among all the RGB pixels.

Next, the light-emitting layer 42 of red color is formed to have a thickness of, for example, 30 nm on the positive hole transport layer 41 in the associated pixel regions via a mask. The light-emitting layer 42 of red color is made of a mixture of 2,6-bis((4′-methoxydiphenylamino)styryl)-1,5-dicyanonaphthalene (BSN) with di(2-naphthyl)anthracene (ADN), the concentration of BSN being 30 wt %.

After that, the light-emitting layer 42 of green color is formed to have a thickness of, for example, 30 nm on the positive hole transport layer 41 in the associated pixel regions via a mask. The light-emitting layer 42 of green color is made of a mixture of coumarin 6 with ADN, the concentration of coumarin 6 being 5 wt %.

Then, the light-emitting layer 42 of blue color is formed to have a thickness of, for example, 30 nm on the positive hole transport layer 41 in the associated pixel regions via a mask. The light-emitting layer 42 of blue color is made of a mixture of 4,4′-bis(2-{4-(N,N-diphenylamino)phenyl}vinyl)biphenyl (DPAVBi) with ADN, the concentration of DPAVBi being 2.5 wt %.

Next, a layer of 8-hydroxyquinoline aluminum (Alq₃) is formed, via a mask, as the electron transport layer 43 to have a thickness of, for example, 20 nm, in common among all the RGB pixels on the light-emitting layers 42 of all the colors.

After that, a layer of lithium fluoride (LiF) is formed, via a mask, as the electron injection layer 44 to have a thickness of, for example, 0.3 nm on the electron transport layer 43.

Then, the second electrode 14 of aluminum (Al) is formed to have a thickness of, for example, 10 nm by vacuum vapor deposition.

Next, as illustrated in FIG. 9, a second sealing film 6 is formed on a surface of the organic EL element layer 5.

More specifically, silicon nitride (SiNₓ, where x is a positive number) such as Si₃N₄ is deposited by plasma CVD, vacuum vapor deposition, sputtering, atomic layer deposition (ALD) or other methods, thereby forming a barrier layer 6a (having a thickness of, e.g., 500 nm) on the surface of the organic EL element layer 5.

Next, for example, silicon carbonitride (SiCN) is deposited by plasma CVD, vacuum vapor deposition, sputtering, atomic layer deposition (ALD) or other methods, thereby forming a stress relief layer 6b (having a thickness of, e.g., 500 nm) on a surface of the barrier layer 6a.

Thereafter, as illustrated in FIG. 5, a barrier layer 6c, a stress relief layer 6d, a barrier layer 6e, a stress relief layer 6f, and a barrier layer 6g (each having at thickness of, e.g., 500 nm) are sequentially stacked on or above the stress relief layer 6b. In this manner, the second sealing film 6 is formed on the surface of the organic EL element layer 5.

At this time, the second sealing film 6 is formed to be in contact with the first sealing film 3. Thus, the second sealing film 6 and the first sealing film 3 together cover the organic EL element layer 5.

The barrier layers 6c, 6e, and 6g are formed in the same manner as the barrier layer 6a described above. The stress relief layers 6d and 6f are formed in the same manner as the stress relief layer 6b described above.

Next, a sealer 2 is provided to cover the interface 25 between the first and second sealing films 3 and 6 (i.e., the contact portion between the first and second sealing films 3 and 6).

More specifically, in an atmosphere of nitrogen, the above-described material such as epoxy resin is applied onto the substrate 26 shown in FIG. 9 by dispending, mask printing, flexography, or other methods, thereby forming the sealer 2 covering the interface 25 between the first and second sealing films 3 and 6.

Next, the substrate 26 is irradiated with UV, or heated to cure the resin forming the sealer 2.

In the above manner, the organic EL display device 1 of this embodiment can be produced.

The embodiment described above provides the following advantages.

(1) In this embodiment, the sealer 2 is provided to cover the interface 25 between the first and second sealing films 3 and 6. This configuration can prevent the interface 25 between the first and second sealing films 3 and 6 from being exposed, enabling prevention of entry of moisture through the boundary between the first and second sealing films 3 and 6. This makes it possible to prevent deterioration of the organic EL elements 7 which may be caused by moisture.

### Second Embodiment

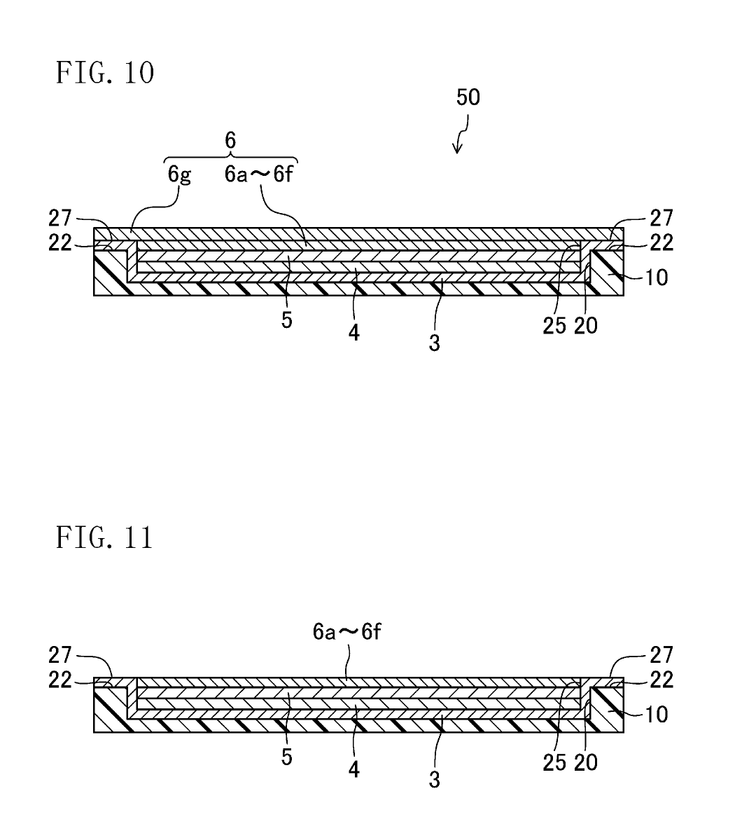

A second embodiment of the present invention will now be described. FIG. 10 is a cross-sectional view of an organic EL display device according to the second embodiment of the present invention. The same reference numerals as those in the first embodiment are used to represent equivalent elements, and the detailed explanation thereof will be omitted.

The organic EL display device 50 of this embodiment has the following feature: instead of the sealer 2 described above, the barrier layer 6g covers the interface 25 between the first and second sealing films 3 and 6. As shown in FIG. 5, the barrier layer 6g is located opposite to the organic EL element layer 5, and is the outermost layer of the barrier layers 6a, 6c, 6e, and the stress relief layers 6b, 6d, 6f that form the second sealing film 6.

Like the first embodiment described above, this configuration, in which the barrier layer 6g can prevent the interface 25 between the first and second sealing films 3 and 6 from being exposed, enables prevention of entry of moisture through the boundary between the first and second sealing films 3 and 6. This makes it possible to prevent deterioration of the organic EL elements 7 which may be caused by moisture.

As illustrated in FIG. 10, in the organic EL display device 50 of this embodiment, the outermost barrier layer 6g covers upper surfaces 27 of end portions of the first sealing film 3. This configuration can effectively prevent entry of moisture which may be caused by age deterioration of the first sealing film 3.

An exemplary method for manufacturing the organic EL display device according to this embodiment will now be described. FIG. 11 is a cross-sectional view illustrating the exemplary method for manufacturing the organic EL display device according to the second embodiment of the present invention.

First, in the same manner as illustrated in FIGS. 6 to 8 of the first embodiment described above, a first sealing film 3 is formed on a plastic substrate 10 having a recess 20 formed therein. A thin-film transistor layer 4 is then formed on the first sealing film 3, and an organic EL element layer 5 is formed on the thin-film transistor layer 4.

Next, a second sealing film 6 is formed on a surface of the organic EL element layer 5. Specifically, as illustrated in FIG. 11, a barrier layer 6a, a stress relief layer 6b, a barrier layer 6c, a stress relief layer 6d, a barrier layer 6e, and a stress relief layer 6f are stacked in this order on or above the organic EL element layer 5, in the same manner as in the first embodiment described above.

Next, a barrier layer 6g is formed, as the outermost layer located opposite to the organic EL element layer 5, on a surface of the stress relief layer 6f, in the same manner as in the first embodiment described above. The barrier layer 6g is formed so as to cover the interface 25 between the first and second sealing films 3 and 6, and the upper surfaces 27 of the end portions of the first sealing film 3, as illustrated in FIG. 10.

In this manner, the organic EL display device 50 of this embodiment can be produced.

The embodiment described above provides the following advantages.

(2) In this embodiment, the barrier layer 6g is provided to cover the interface 25 between the first and second sealing films 3 and 6. This configuration can prevent the interface 25 between the first and second sealing films 3 and 6 from being exposed, enabling prevention of entry of moisture through the boundary between the first and second sealing films 3 and 6. This makes it possible to prevent deterioration of the organic EL elements 7 which may be caused by moisture.

(3) Unlike the first embodiment described above, the sealer 2 does not have to be provided. Thus, this embodiment makes it possible to prevent deterioration of the organic EL elements 7 which may be caused by moisture, without incurring additional cost.

(4) The barrier layer 6g covers the upper surfaces 27 of the end portions of the first sealing film 3. This configuration can effectively prevent entry of moisture which may be caused by age deterioration of the first sealing film 3.

The embodiments described above may be modified as follows.

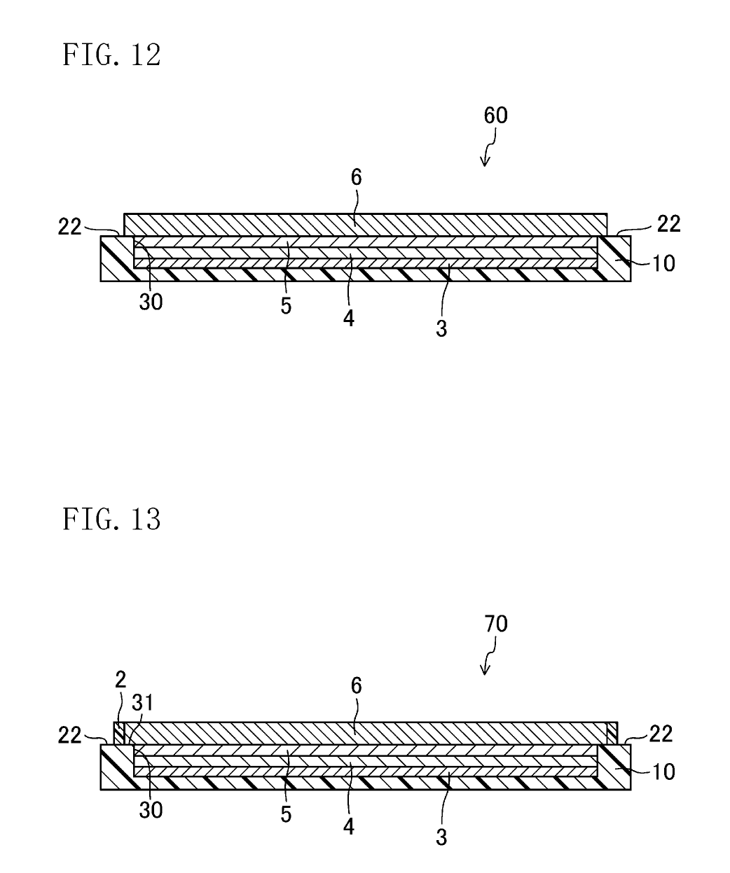

FIG. 12 illustrates an organic EL display device 60 which has a modified configuration. Specifically, a second sealing film 6 is provided on an organic EL element layer 5 such that the second sealing film 6 is in contact with upper surfaces 22 of end portions of a substrate 10. Thus, the second sealing film 6 covers the interface 30 between the substrate 10 and the organic EL element layer 5.

In this case, it is suitable that the upper surface of the organic EL element layer 5 adjacent to the second sealing film 6 is located closer to the first sealing film 3 than the upper surfaces 22 of the end portions of the substrate 10 are.

This configuration can prevent the interface 30 between the substrate 10 and the organic EL layer 5 from being exposed, enabling prevention of entry of moisture through the boundary between the substrate 10 and the organic EL layer 5. This makes it possible to prevent deterioration of the organic EL elements 7 which may be caused by moisture.

FIG. 13 illustrates an organic EL display device 70 which has another modified configuration. Specifically, the organic EL display device 70 corresponds to the organic EL display device 60 illustrated in FIG. 12, to which a sealer 2 is added. The sealer 2 is provided on the upper surfaces 22 of the end portions of the substrate 10 to be in contact with the second sealing film 6 and to cover the interface 31 between the substrate 10 and the second sealing film 6.

This configuration can prevent the interface 31 between the substrate 10 and the second sealing film 6 from being exposed, enabling prevention of entry of moisture through the boundary between the substrate 10 and the second sealing film 6. This makes it possible to prevent deterioration of the organic EL elements 7 which may be caused by moisture.

In each of the embodiments described above, the flexible plastic substrate 10 is used as the substrate. However, this is a mere example. A glass substrate having a recess 20 for receiving the thin-film transistor layer 4 and the organic EL element layer 5 may be used. In this case, the recess may be formed in the glass substrate by, for example, etching, grinding, or other methods.

In the embodiments described above, the second sealing film 6 includes the four barrier layers and the three stress relief layers. However, the numbers of the barrier layers and the stress relief layers are not particularly limited, as long as one barrier layer is provided as the outermost layer located opposite to the organic EL element layer 5.

### INDUSTRIAL APPLICABILITY

As can be seen from the foregoing description, the present invention is suitable for an organic EL display device including an organic EL element.

### DESCRIPTION OF REFERENCE CHARACTERS

1 Organic EL Display Device

2 Sealer

3 First Sealing Film

4 Thin-film Transistor Layer

5 Organic EL Element Layer

6 Second Sealing Film

10 Substrate

6g Outermost Barrier Layer Opposite to Organic EL Element Layer

10 Plastic Substrate

22 Upper Surface of End Portion of Substrate

25 Interface between First and Second Sealing Films

27 Upper Surface of End Portion of First Sealing Film

50 Organic EL Display Device

60 Organic EL Display Device

70 Organic EL Display Device

1. An organic EL display device comprising:
a substrate;
a first sealing film on the substrate;
an organic EL element layer above the first sealing film; and
a second sealing film provided on the organic EL element layer, being in contact with the first sealing film, and covering, together with the first sealing film, the organic EL element layer, wherein
a sealer is provided to cover an interface between the first and second sealing films.

2. The organic EL display device of claim 1, wherein
the substrate includes a recess for receiving the organic EL element layer, and the first sealing film is formed on a surface of the recess.

3. The organic EL display device of claim 1, wherein
the substrate is embodied as a flexible plastic substrate or a glass substrate.

4. An organic EL display device comprising:
a substrate;
a first sealing film on the substrate;
an organic EL element layer above the first sealing film; and
a second sealing film provided on the organic EL element layer, being in contact with the first sealing film, and covering, together with the first sealing film, the organic EL element layer, wherein
the second sealing film includes a plurality of barrier layers and a plurality of stress relief layers stacked alternately, and
an outermost barrier layer of the plurality of barrier layers located opposite to the organic EL element layer covers an interface between the first and second sealing films.

5. The organic EL display device of claim 4, wherein
the outermost barrier layer covers an upper surface of an end portion of the first sealing film.

6. The organic EL display device of claim 4, wherein
the substrate includes a recess for receiving the organic EL element layer, and the first sealing film is formed on a surface of the recess.

7. The organic EL display device of claim 4, wherein
the substrate is embodied as a flexible plastic substrate or a glass substrate.

8. An organic EL display device comprising:
a substrate;
a first sealing film on the substrate;
an organic EL element layer above the first sealing film; and
a second sealing film provided on the organic EL element layer, being in contact with an upper surface of an end portion of the substrate, and covering an interface between the substrate and the organic EL element layer.

9. The organic EL display device of claim 8, wherein
a sealer is provided to cover the interface between the substrate and the second sealing film.
